(19) United States
(12) Patent Application Publication
(10) Pub. No.: US 2012/0098004 A1
(43) Pub. Date: Apr. 26, 2012

(54) LIGHT EMITTING DIODE PACKAGE

(75) Inventors: CHIH-HSUN KE, Hukou (TW); SHIUN-WEI CHAN, Hukou (TW)

(73) Assignee: ADVANCED OPTOELECTRONIC TECHNOLOGY, INC., Hsinchu Hsien (TW)

(21) Appl. No.: 13/171,468

(22) Filed: Jun. 29, 2011

(30) Foreign Application Priority Data
Oct. 26, 2010 (CN) 201010517859.1

(51) Int. Cl. H01L 33/60

(52) U.S. Cl. 257/98; 257/E33.072

(57) ABSTRACT

An LED package includes a substrate, an LED die and an encapsulation. The substrate includes a supporting surface and a protrusion extending from the supporting surface along a first direction. The protrusion includes a distal end portion extending along a second direction. The first direction and the second direction define a non-zero angle there between. The LED die is arranged on the supporting surface of the substrate. The encapsulation lies on the supporting surface and covers the LED die and the protrusion to increase a bonding connection between the encapsulation and the substrate.

### BACKGROUND

1. Technical Field

The present disclosure generally relates to light emitting diode (LED) packages.

2. Description of Related Art

Generally, an LED package includes a substrate, an LED die arranged on the substrate, and an encapsulation formed on the substrate to cover the LED die. However, due to that the substrate and the encapsulation are usually made of different materials, they can not combine together with sufficient strength. Weak bonding strength between the substrate and the encapsulation leads to poor reliability of the LED package.

Therefore, it is necessary to enhance bonding strength between the substrate and the encapsulation of LED packages to enhance the reliability of the LED package.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a cross-sectional view of an LED package in accordance with a first embodiment of the present disclosure.

FIG. 2 is a top view of the LED package of FIG. 1.

FIG. 3 is a cross-sectional view of an LED package in accordance with a second embodiment of the present disclosure.

FIG. 4 is a cross-sectional view of an LED package in accordance with a third embodiment of the present disclosure.

FIG. 5 is a top view of the LED package of FIG. 4.

FIG. 6 is a cross-sectional view of an LED package in accordance with a fourth embodiment of the present disclosure.

FIG. 7 is a top view of the LED package of FIG. 6.

FIG. 8 is a cross-sectional view of an LED package in accordance with a fifth embodiment of the present disclosure.

### DETAILED DESCRIPTION

Reference will now be made to the drawings to describe the present LED package in detail.

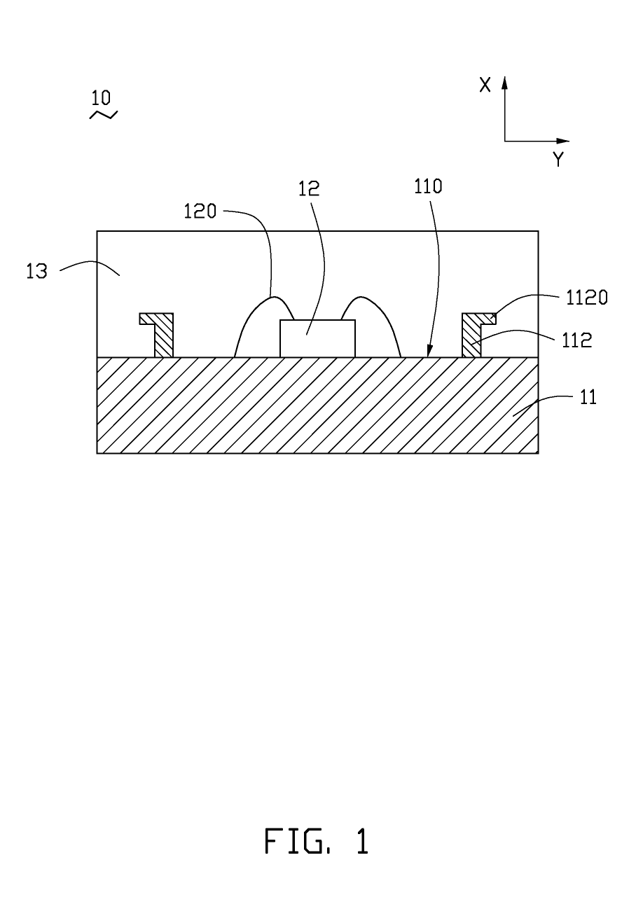

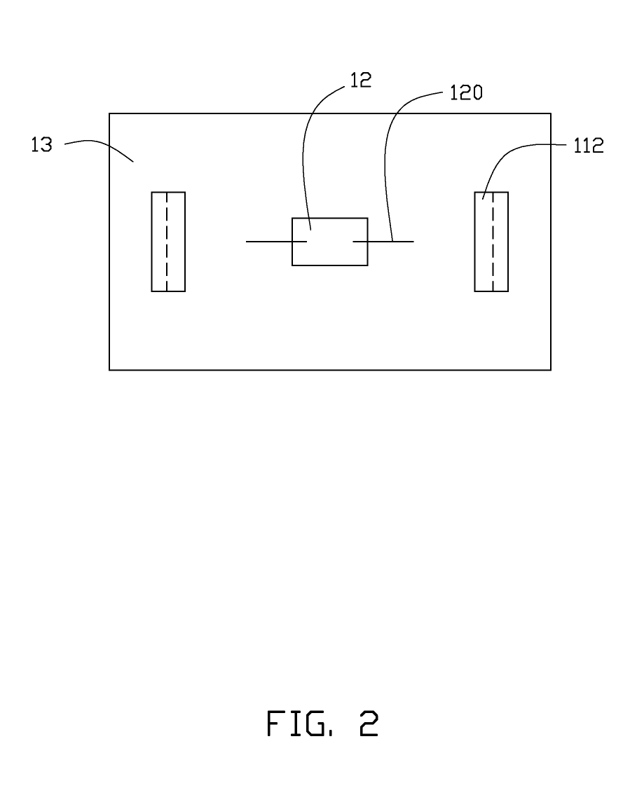

Referring to FIG. 1 and FIG. 2, an LED package 10 according to a first embodiment includes a substrate 11, an LED die 12 and an encapsulation 13.

The substrate 11 can be rectangular, circular or other desired shapes according to an actual requirement. The substrate 11 can be made of materials with excellent thermal conductivity, such as ceramic, metal and so on. In this embodiment, the substrate 11 is rectangular and made of ceramic.

The substrate 11 includes a supporting surface 110 and at least one protrusion 112 extending from the supporting surface 110. A circuit/trace (not illustrated) is configured in an interior of the substrate 11 or on the supporting surface 110 of the substrate 11, to transfer electrical power to the LED die 12.

The supporting surface 110 is configured for supporting the LED die 12. Optical properties and a curvature of the supporting surface 110 can be adjusted according to an actual requirement of design. For example, the supporting surface 110 can be designed to be reflective to improve light extraction efficiency. Besides, the supporting surface 110 can be designed to be a flat plane or a curved surface to satisfy different optical requirements for the LED package 10, which may require the LED package 10 to be a point light source or a surface light source. In this embodiment, the supporting surface 110 is a reflective, flat plane.

The at least one protrusion 112 extends along an x-direction (as illustrated in FIG. 1) away from the supporting surface 110, and then a distal end 1120 of the at least one protrusion 112 extends along a y-direction (as illustrated in FIG. 1), which designate a lateral direction of the substrate 11. In alternated embodiment, the distal end 1120 can extend along a front-to-rear direction of the substrate 1120. The x-direction and the y-direction define a non-zero angle there between. In the present embodiment, the x-direction is perpendicular to the supporting surface 112 of the substrate 11, and the y-direction is perpendicular to the x-direction. In this embodiment, the substrate 11 includes two opposite protrusions 112. It is well understood that the amount of the protrusion 112 can also be three, four or more.

The LED die 12 is arranged on the supporting surface 110. Electrodes (not illustrated) of the LED die 12 are electrically connected to the circuit/trace (not illustrated) of the substrate 11. In this embodiment, the electrodes of the LED die 12 are connected to the circuit/trace of the substrate 11 by metal wires 120.

The encapsulation 13 is configured on the supporting surface 110 and covers the LED die 12 and the protrusions 112. The encapsulation 13 can be made of light pervious materials. The encapsulation 13 can be equipped with wavelength converting substances (not illustrated) to enable light emitted from the LED package 10 to have the desired color. The wavelength converting substances can be distributed in an interior or on a light output surface of the encapsulation 13.

Due to the extending direction (y-direction) of the distal end 1120 being different from a main portion of the protrusion 112, a hook shaped configuration is formed, and a bonding strength between the substrate 11 and the encapsulation 13 is increased thereby.

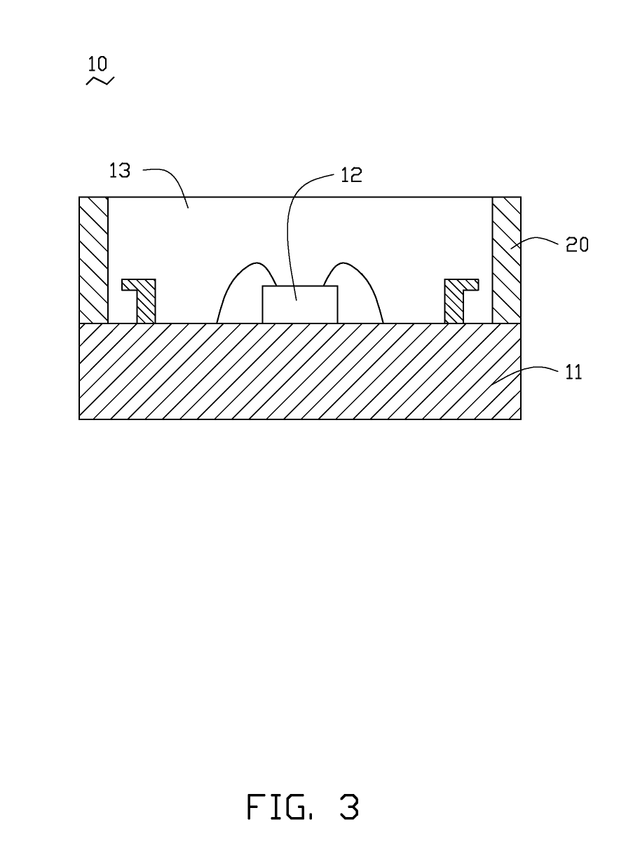

Referring to FIG. 3, according to a second embodiment, the LED package 10 can further be equipped with a reflective cup 20. The reflective cup 20 surrounds the LED die 12 to collimate light emitting from the LED die 12.

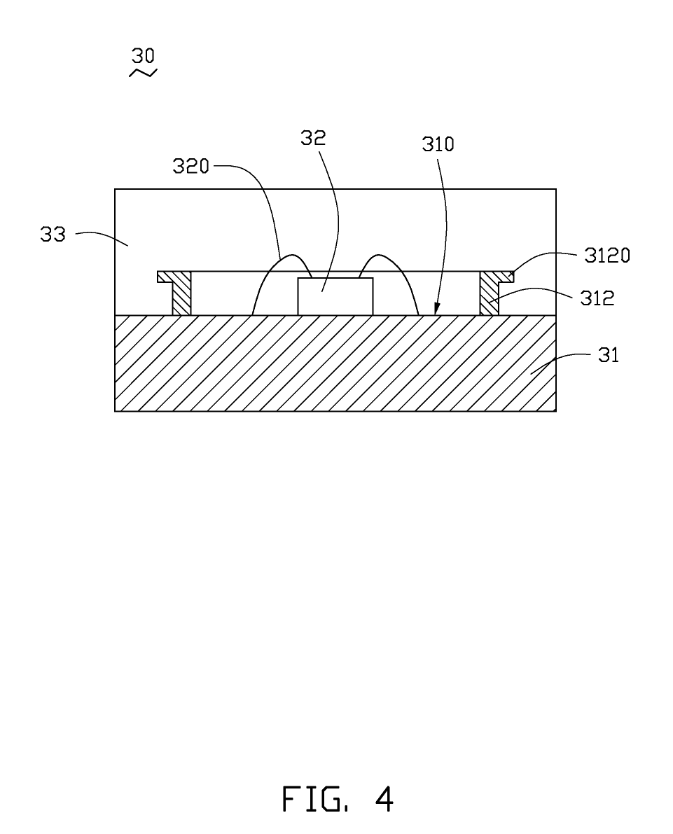

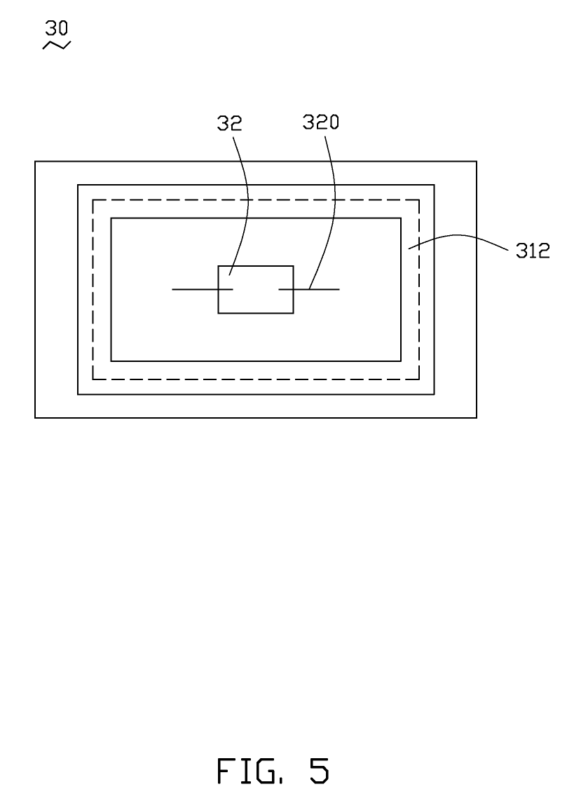

Referring to FIG. 4 and FIG. 5, an LED package 30 according to a third embodiment includes a substrate 31, an LED die 32 and an encapsulation 33 arranged on the substrate 31. The substrate 31 includes a supporting surface 310 and a protrusion 312 extending from the supporting surface 310. The protrusion 312 has a shape like a flanged, rectangular sleeve which forms a closed loop surrounding the LED die 32. The protrusion 312 includes an end portion 3120 extending toward an outer periphery of the substrate 31.

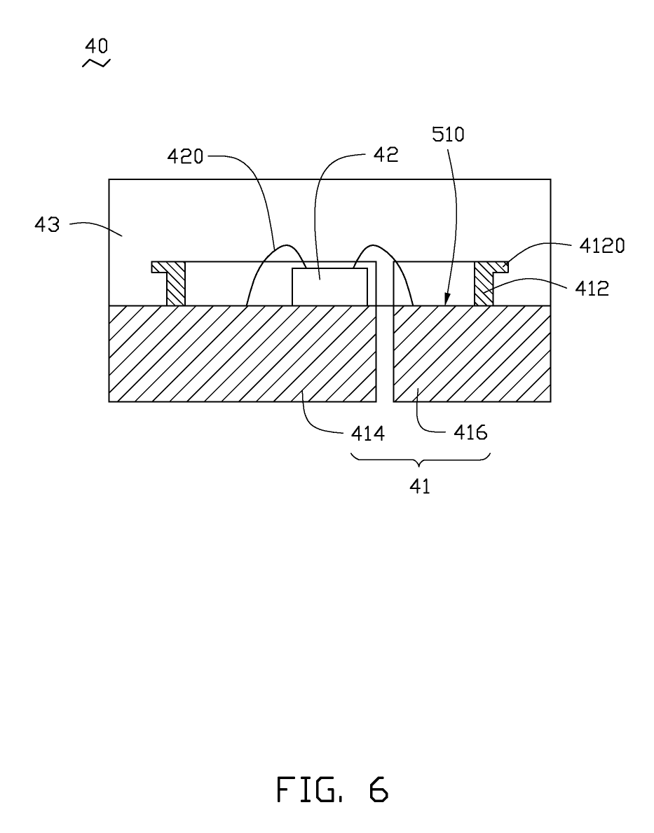

Referring to FIG. 6, an LED package 40 according to a fourth embodiment includes a substrate 41, an LED die 42 and an encapsulation 43 arranged on the substrate 41. The substrate 41 includes a supporting surface 410 and a protrusion 412 extending from the supporting surface 410. The protrusion 412 is substantially the same as the protrusion 312; the difference therebetween is that the protrusion 412 is formed by severing the protrusion 312 into two parts with a gap therebetween. The protrusion 412 surrounds the LED die 42, and includes an end portion 4120 extending toward an outer periphery of the substrate 41.

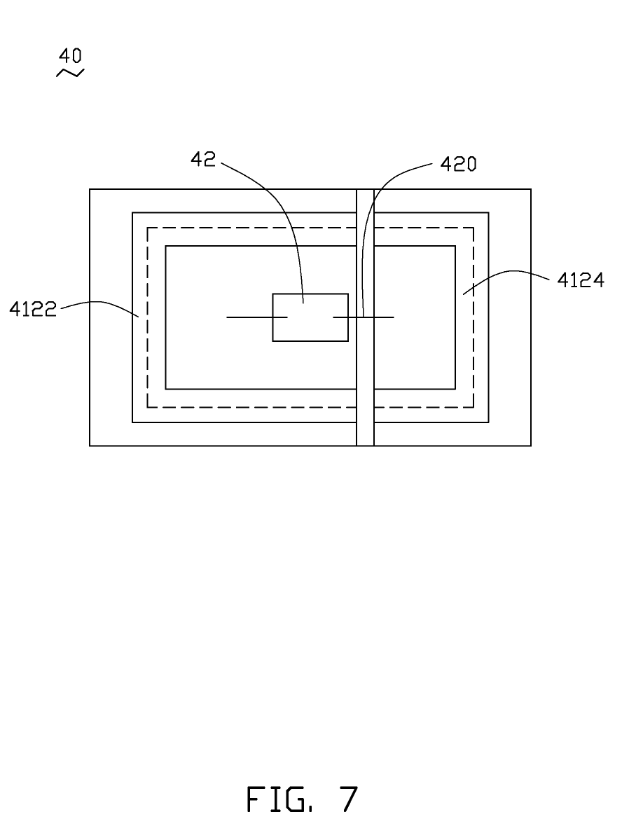

The substrate 41 is made of electrically conductive materials, and comprises a first portion 414 and a second portion 416 electrically insulated from the first portion 414. The LED die 42 is arranged on the first portion 414. Electrodes of the LED die 42 are respectively connected to the first portion 414 and the second portion 416 by metal wires 420. Accordingly, the first portion 414 and the second portion 416 respectively act as positive and negative electrodes of the LED die 42. In this embodiment, the substrate 41 is made of metal, whereby the first portion 414 can help dissipation of heat generated by the LED die 42. It is to be said that, the protrusion 412 includes a first part 4122 extending from the first portion 414 of the substrate 41, and a second part 4124 extending from the second portion 416 of the substrate 41. The first part 4122 and the second part 4124 cooperatively form a discontinuous loop surrounding the LED die 42, as illustrated in FIG. 7.

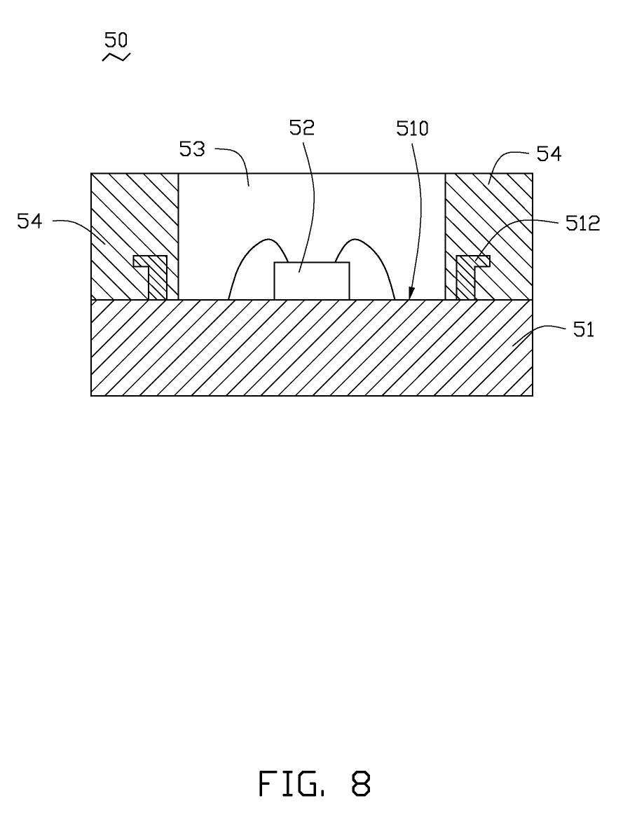

Referring to FIG. 8, an LED package 50 according to a fifth embodiment includes a substrate 51, an LED die 52, an encapsulation 53 and a reflective cup 54 arranged on the substrate 51.

The substrate 51 includes a supporting surface 510 and two protrusions 512 extending from the supporting surface 510. The two protrusion 512 each include an end portion (not labeled) extending toward an outer lateral side of the substrate 51. The reflective cup 54 is arranged on the supporting surface 510 and surrounds the LED die 52. The two protrusions 512 are embedded into an interior of the reflective cup 54, thereby increasing bonding strength between the substrate 51 and the reflective cup 54.

The substrate 51 can be made of materials as those disclosed in the previous embodiments for forming the substrates 11, 31, 41. The amount and configuration of the protrusions 512 can also be modified as disclosed above for the previous embodiments. Furthermore, it can be understood by a person skilled in the art that the protrusions 112 shown in the first embodiment which engage with the encapsulation 13 can also be provided in this embodiment to engage with the encapsulation 53 to increase the bonding strength between the substrate 51 and the encapsulation 53.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. An LED package comprising:
a substrate comprising a supporting surface and a protrusion, the protrusion extending from the supporting surface along a first direction with a distal end portion thereof extending along a second direction, the first direction and the second direction defining a non-zero angle therebetween;
an LED die arranged on the supporting surface of the substrate; and
an encapsulation lying on the supporting surface and covering the LED die and engaging with the protrusion to thereby increase a connection strength between encapsulation and the substrate.

2. The LED package according claim 1, wherein the first direction is perpendicular to the supporting surface of the substrate.

3. The LED package according claim 2, wherein the second direction is perpendicular to the first direction.

4. The LED package according claim 1, wherein the substrate is electrically conductive, and the substrate comprises a first portion and a second portion electrically insulated from each other.

5. The LED package according claim 4, wherein the LED die is arranged on the first portion of the substrate and has two electrodes, one electrode of the LED die is electrically connected to the first portion of the substrate, and the other electrode of the LED die is electrically connected to the second portion of the substrate.

6. The LED package according claim 4, wherein the first portion and the second portion each have at least one protrusion extending therefrom.

7. The LED package according claim 6, wherein the protrusions extending from the first and second portions cooperatively form a discontinuous loop.

8. The LED package according claim 7, wherein the discontinuous loop surrounds the LED die.

9. The LED package according claim 1, wherein the encapsulation covers both of the LED die and the protrusion.

10. The LED package according claim 1, further comprising a reflective cup surrounding the LED die and the encapsulation, the reflective cup being arranged on the supporting surface.

11. The LED package according to claim 10, wherein the reflective cup engages with another protrusion extending upwardly from the substrate.
